(19) United States
(12) Patent Application Publication
(10) Pub. No.: US 2008/0265348 A1
(43) Pub. Date: Oct. 30, 2008

(54) Method of Manufacturing an Image Sensor and Image Sensor

(75) Inventors: Joris Maas, Eindhoven (NL); Leendert De Bruin, Eindhoven (NL); Daniel Wilhelmus Elisabeth Verbugt, Eindhoven (NL); Nicolaas Johannes Anthonius Van Veen, Eindhoven (NL); Eric Cornelis Egbertus Van Grunsven, Eindhoven (NL); Gerardus Lubertus Jacobus Reuvers, Nijmegen (NL); Erik Harold Groot, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/570,248

(22) PCT Filed: May 12, 2005
(86) PCT No.: PCT/IB2005/051560

§ 371 Date: Dec. 8, 2006

(30) Foreign Application Priority Data
Jun. 9, 2004 (EP) 04102618.8
Nov. 5, 2004 (EP) 04105544.3

(51) Int. Cl. H01L 31/0232; H01L 21/86

(52) U.S. Cl. 257/432; 438/70; 257/E31.127; 257/E21.704

(57) ABSTRACT

A method of manufacturing a back-side (14) illuminated image sensor (1) is disclosed, comprising the steps of: starting with a wafer (2) having a first (3) and a second surface (4), providing light sensitive pixel regions (5) extending into the wafer (2) from the first surface (3), securing the wafer (2) onto a protective substrate (7) such that the first surface (3) faces the protective substrate, the wafer comprising a substrate of a first material (8) with an optical transparent layer (9) and a layer of semiconductor material (10), wherein the substrate (8) is selectively removed from the layer of semiconductor material by using the optical transparent layer (9) as stopping layer. For back-side illuminated image sensors, light has to transmit through the semiconductor layer and enter into the light sensitive pixel regions (5). In order to reduce absorption losses, it is very advantageous that the semiconductor layer (10) can be made relatively thin with a good uniformity. Because of the reduced thickness of the semiconductor layer, more light can enter into the light sensitive regions, resulting in an improved efficiency of the image sensor.

The invention relates to a method of manufacturing a back-side illuminated image sensor, comprising the steps of:

starting with a wafer having a first and a second surface,

providing light sensitive pixel regions extending into the layer of the wafer from the first surface,

securing the wafer onto a protective substrate such that the first surface faces the protective substrate.

The invention further relates to an image sensor comprising a semiconducting layer having a first and a second surface, the semiconductor layer comprising light sensitive regions extending into the semiconductor layer from the first surface, the second surface of the semiconductor layer having an optical transparent layer through which light enters through the semiconductor layer in the light sensitive pixel regions, the first surface of the semiconducting layer facing a protective substrate.

U.S. Pat. No. 6,168,965 discloses a method for producing a back-illuminated image sensor including a matrix of pixels (e.g. CMOS APS pixels) that are manufactured on a semiconductor substrate. The semiconductor substrate is secured to a protective substrate by an adhesive such that the processed frontside surface of the semiconductor substrate faces the protective substrate. With the protective substrate providing structural support, the exposed back-side surface of the semiconductor substrate is then subjected to grinding and/or etching, followed by optional chemical/mechanical processing, to thin the transparent substrate to a range of 10 to 15 microns. A transparent substrate (e.g. glass) is then secured to the back-side surface of the semiconductor substrate, thereby sandwiching the semiconductor substrate between the transparent substrate and the protective substrate.

Thinning of the transparent surface is a very non-uniform process in which thickness variations of the semiconductor substrate results in differences in absorption.

The known image sensor therefore has the disadvantage that the efficiency is limited and the variance in absorption of light is unacceptable high, in particular for the short wavelengths (blue).

It is an object of the invention to provide a method of manufacturing an image sensor in which the efficiency is improved and the absorption variances are reduced.

This object of the invention is achieved in that the wafer comprises a substrate of a first material with an optical transparent layer and a layer of semiconductor material, wherein the substrate is selectively removed using the optical transparent layer as stopping layer.

The substrate can be selectively removed from the optical transparent layer by using selective removal techniques towards the stopping layer. Such removal techniques may be wet chemical etching and/or chemical mechanical polishing (CMP). The removal rate of the stopping layer should be much less than the removal rate of the substrate material. For back-side illuminated image sensors, light has to transmit through the semiconductor layer and enter into the light sensitive pixel regions. It is therefore very advantageous that the semiconductor layer can be made relatively thin.

Because of the reduced thickness of the semiconductor layer, more light can enter into the light sensitive regions, resulting in an improved efficiency of the image sensor. In particular short wavelength light benefits from a reduced semiconductor layer thickness.

Because the thickness and uniformity of the semiconductor layer can be very well controlled, absorption differences between pixels and sensors are significantly reduced.

Back-side illumination has many advantages compared to conventional image sensors which are illuminated from the front-side. In conventional image sensors the pixels are driven by connection wires, which are usually manufactured from metal or poly-silicon layers. These layers are not transparent for light, so that incoming light can not reach the entire pixel area. There is a continuous drive to reduce the pixel area to reduce costs. However, the further reduction of the pixel area in front-side illuminated image sensors inherently results in a relative smaller part of the pixel area being sensitive to light.

In this invention where back-side illumination is applied, the poly or metal connection wires no longer determine the light sensitive area of the pixel. The entire pixel area is sensitive to light, allowing a 100% fill factor. So advantages are, amongst others, an improved sensitivity, the angles of incoming light (CRA) can be larger and there is more freedom in the design of the layout of connection wires. A larger chief ray angle (CRA) can result in a lower camera module because one lens element (e.g of a VGA lens in a camera module) may be omitted. This improves sensitivity (e.g. reduction of 2-4% in reflection losses) and reduces the costs. Also the building height of the module is lower which is important because of the miniaturization drive. Because of the trade-off between the Module Transfer Function (MTF) and the F-number, (MTF is a measure for the sharpness and contrast, and the F-number is a measure for the lens opening (diafragma)), the extent to which the MTF and F-number can be improved with back-side illumination is exchangeable.

It is advantageous when the optical transparent layer is a buried oxide layer of a silicon on insulator (SOI) wafer. The buried oxide of the SOI wafer can be used as an etch stop layer during removal of the silicon substrate. Nowadays, commercially available SOI wafers have an epitaxial semiconductor layer with a thickness of the order of 100 nm. After removal of the substrate, the remaining epitaxial semiconductor layer still has the initial thickness and is very uniform. For amorphous and epitaxial semiconductor layers, thickness and uniformity can be controlled within a few nanometers.

It is another major advantage that the thin epitaxial semiconductor surface remains protected by the buried oxide layer in the whole process. The surface of the semiconductor is not attached by processing, resulting in an almost perfect silicon/oxide interface without any defects, dangling bonds or interface charges.

With an SOI wafer is meant a silicon on insulator substrate. The silicon may be strained. The invention works equally well for Ge on insulator (GeOI) wafers, SiGe or any compound thereof such as SiGeC on insulator wafers. It is advantageous to use SOI wafers, because these are commonly available, while other semiconductor on insulator wafers are still difficult to obtain and are very expensive.

Commercially available SOI wafers usually have an epitaxial semiconductor layer with a thickness of the order of 100 nm. The absorption of light in the light sensitive regions in the semiconductor layer is optimal when the thickness of the semiconductor layer is less than 5 μm, preferably in the range between 1-3 μm. It is therefore desirable to grow an additional semiconductor layer epitaxially on the layer of semiconductor material, to a total thickness of the semiconductor layer of less than 5 microns.

Since the image sensor is back-side illuminated, a color filter may be provided on the optical transparent layer. The color layers may be spin coated and developed after exposure. The color fields (e.g. red, green and blue) of the (RGB) filter are manufactured after each other. Light with a wavelength in the range of 400 and 700 nm is filtered and each wavelength passing the filter is collected in a different light sensitive pixel region.

Apart from the advantages already mentioned, another advantage is the fact that the efficiency of the sensor can be increased by using metal layers as reflectors. A special metallization pattern may be designed which functions as reflector to re-direct light to the light sensitive pixel regions. This is in particular of relevance when the semiconductor layer is much smaller than the total absorption depth of visible light. In that case, light entering from the back-side is reflected by the metallization pattern into the light sensitive pixel regions.

The different metal layers of the multilevel metallization can be used as reflectors for different colors of light. In this way different colors are reflected towards different light sensitive pixel regions.

Special measures are taken to electrically isolate the light sensitive area of the semiconductor epitaxial layer provided with the light sensitive pixel regions from the rest of the semiconductor epitaxial layer. To this end the metallization pattern includes special designed bond pad extensions for making outside contacts to the image sensor.

The outside contacts to the image sensor can be made either from the front side or from the back-side. When the outside contacts are made from the back-side via an opening through the protective layer and the semiconductor layer to the bond pad extensions, an advantage is that the semiconductor layer is removed at the position of the opening. The opening in the semiconductor layer functions as an electrical separation between different dies. Another advantage of making electrical contact from the back-side (side where the light enters), is that the die can be connected easily to other substrates or ICs e.g. by wire bonding or flip-chip techniques. In the opening an electrical conductive stud can be provided, which is placed on the bond pad extensions. Such a stud may be advantageously be used in a stud bumping process.

When the outside contacts are made from the front-side, the advantage is that there are no metal contacts hampering the light, which enters from the back-side. In this case special provisions should be made to obtain electrical isolation between different dies. This is described in the following embodiments.

Seen in perpendicular projection, a first part of the semiconductor layer having overlap with the bond pad extensions is electrically isolated from a second part of the semiconductor layer having the light sensitive pixel regions.

The isolation between the first part and the second part of the semiconductor layer can be formed by a trench extending through the entire semiconductor layer. The trench is filled with an electrical insulating material.

Alternatively the isolation between the first part and the second part of the semiconductor layer can be formed by junction isolation.

In an alternative embodiment, the first part of the semiconductor layer below the bond pads is removed, e.g. by etching.

In order to have a planar surface as long as possible in the manufacturing process, the first part of the semiconductor epitaxial layer is removed late in the process, after the manufacture of the color filters. Because the color filters are made from a photoresist, these layers can also be used as an etch mask for etching the first part of the semiconductor layer below the bond pad extensions.

The color filter processing now can be done on a planar surface, which avoids thickness variations and as a consequence fringing effects later in the visible image of the image sensor.

In another advantageous embodiment of the method the removal of the silicon below the bond pad extensions can even be done after manufacturing of the color filters and the microlenses. After depositing the color filters and the microlenses, a hard etch mask layer, such as a plasma nitride layer, is deposited on the microlenses.

In this way “gapless microlenses” are formed. With this additional layer on top of the micro lenses, there is no spacing between these lenses so that the area of the microlens and the pixel area are the same.

The hard etch mask is used to etch the first part of the semiconductor layer below the bond pads in order to electrical isolate the image sensing region from the rest of the semiconductor layer.

It is a further object of the invention to provide an image sensor in which the efficiency is improved and the absorption variances are reduced.

The object according to the invention is achieved in that part of the light being not absorbed in the semiconductor layer is re-directed into the light sensitive pixel regions by reflection of a metallization pattern. This is in particular of relevance when the semiconductor layer thickness is much smaller than the total absorption depth of visible light. In order to reduce losses, the metal layer facing the light sensitive regions reflects the light being not absorbed in the semiconductor layer and re-directs the light to the light sensitive pixel regions.

Preferably, the metallization pattern is a multilevel metallization pattern, and different colors of light are reflected towards different light sensitive pixel regions.

The efficiency of the sensor can be increased by using a multilevel metallization in which the metal layers function as reflectors.

In an advantageous embodiment the image sensor comprises a metallization pattern provided on the first surface of the semiconductor layer. The metallization pattern may comprise band pad extensions. An outside contact is arranged by connecting the bond-bad extensions via an opening through the semiconductor layer and the protective layer from the back-side (side where the light enters). An electrical contact from the back-side is advantageous because the die can be connected easily to other substrates or ICs e.g. by wire bonding or flip-chip techniques. In the opening an electrical conductive stud or wire bond can be provided, which is placed on the bond pad extensions. Such a stud may be advantageously be used in a stud bumping process.

How the present invention may be put into effect will now be described with reference to the appended schematic drawings. Obviously, numerous variations and modifications can be made without departing from the spirit of the present invention. Therefore, it should be clearly understood that the embodiments of the present invention are illustrative only and not intended to limit the scope of the claims.

The features of the invention will be better understood by reference to the accompanying drawings, which illustrate preferred embodiments of the invention by way of examples. In the drawings:

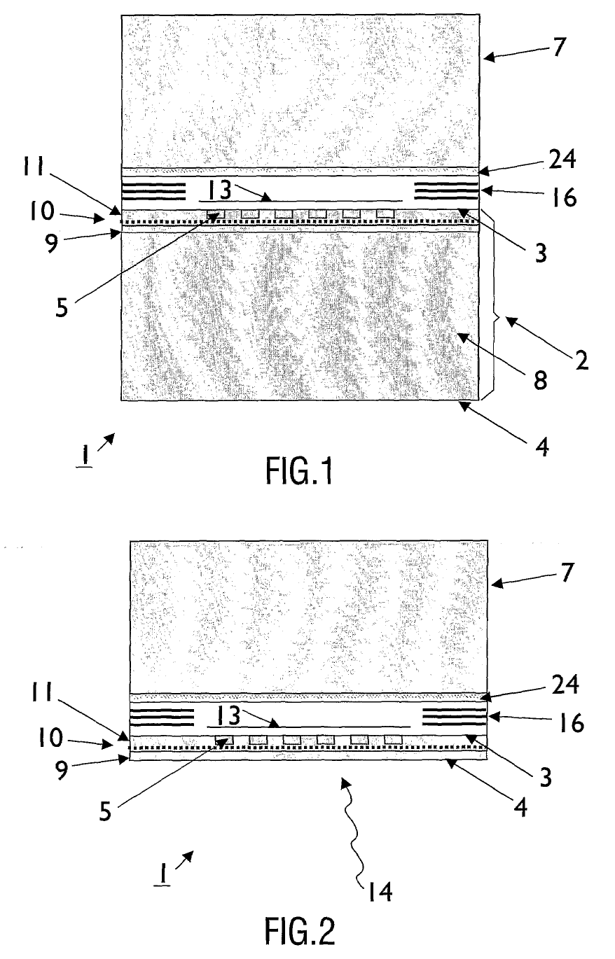

FIG. 1 shows a schematic representation of a CMOS image sensor according to an embodiment of the invention. A protective substrate is glued to the first side of the wafer.

FIG. 2 shows that the substrate is removed, using the buried oxide layer (BOX) as etch stopping layer.

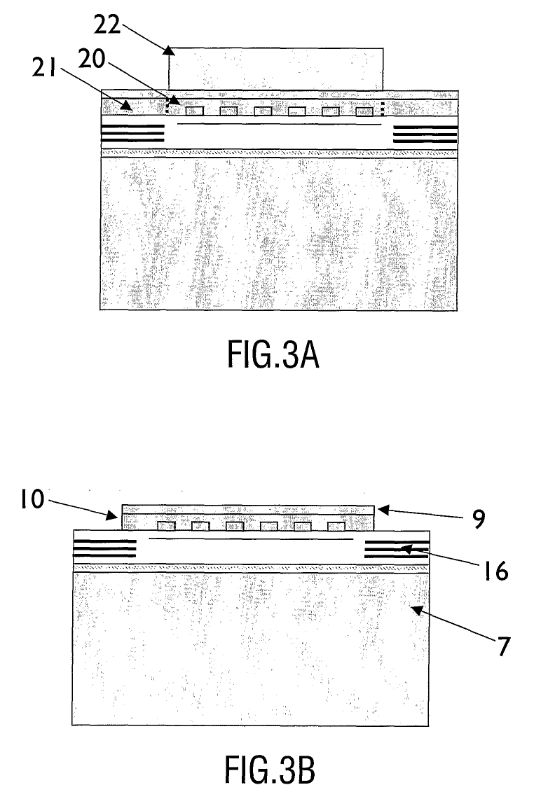

FIGS. 3A and 3B show that the BOX oxide and the Si epi toplayer are etched at the position of the bond pad extensions.

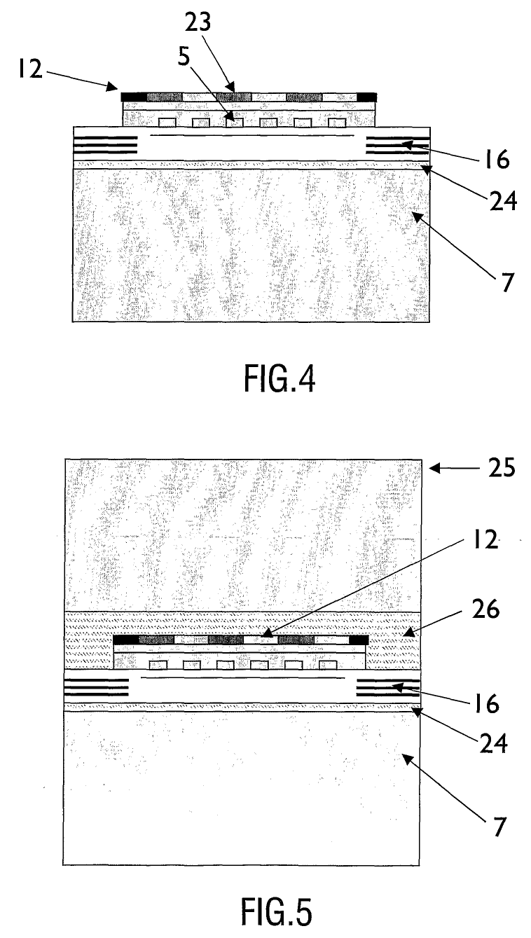

FIG. 4 shows that color filters and micro lenses are provided on the buried oxide layer (BOX).

FIG. 5. shows that a second glass plate is glued on the color filters and micro lenses.

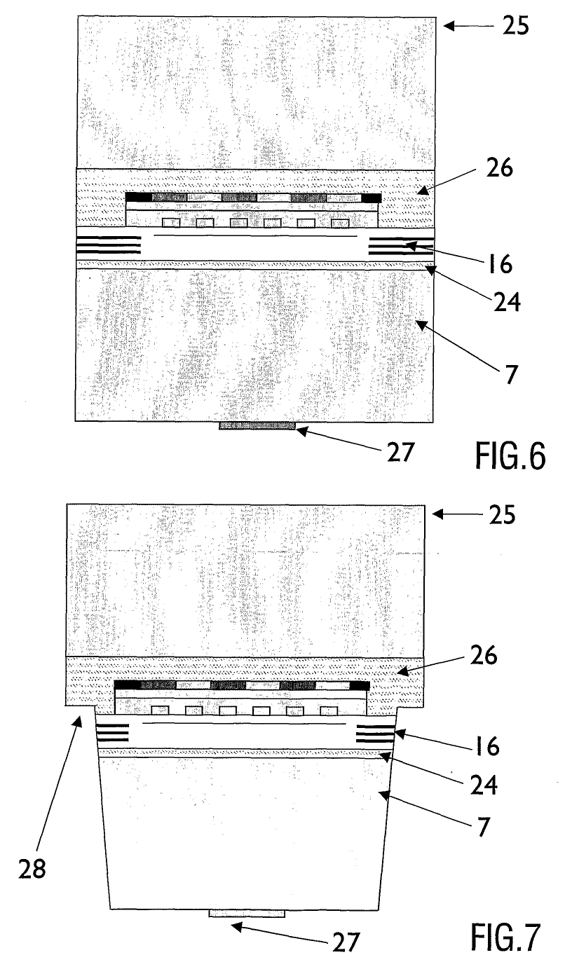

FIGS. 6 to 8 show that contacts from the bond pad extensions to the BGA balls are made.

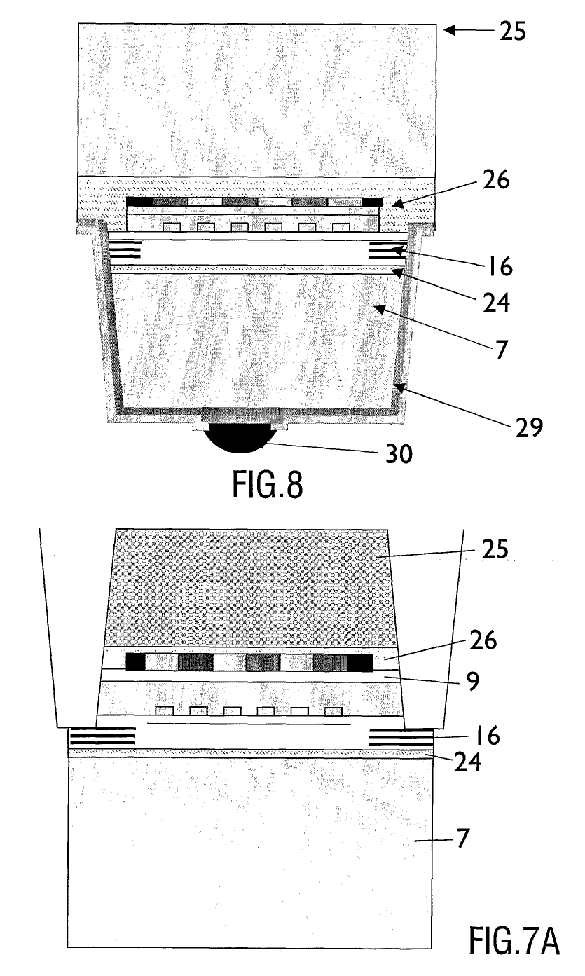

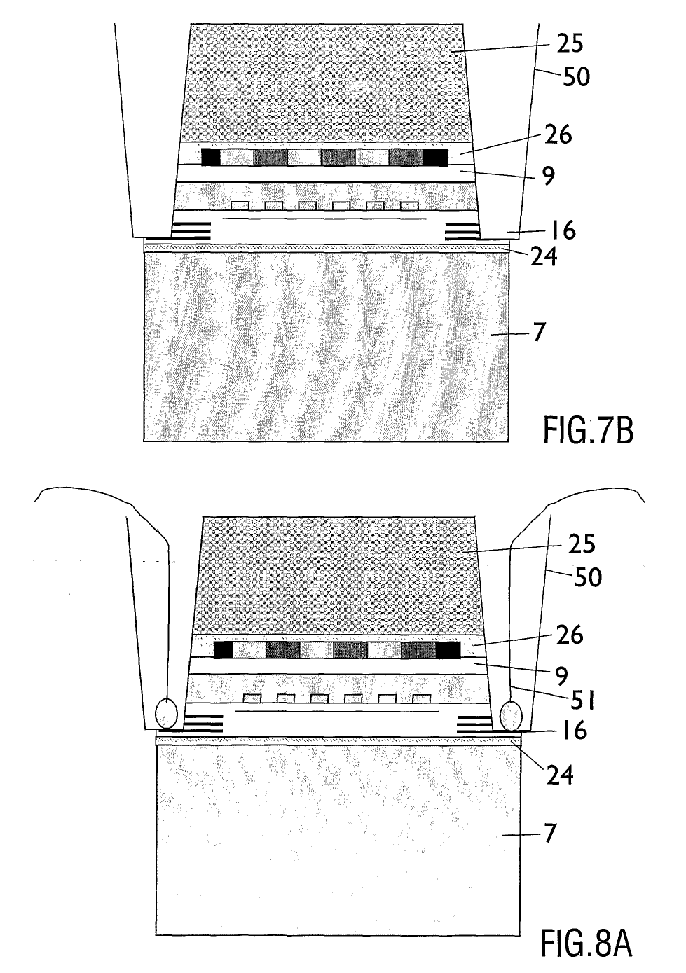

FIGS. 7A-B to 8A show an alternative embodiment in which the bond pad extensions are connected from the back-side.

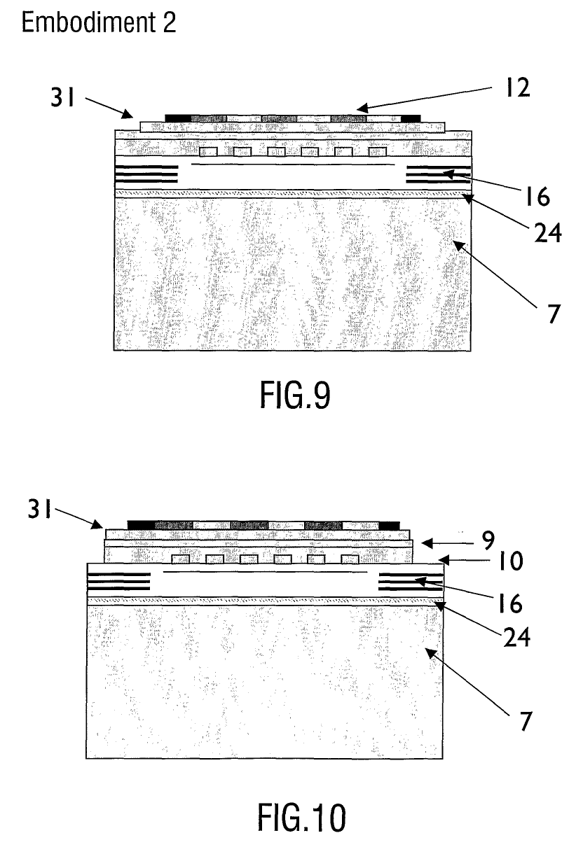

FIGS. 9 and 10 show in a second embodiment the removal of the silicon below the bond pad extensions after manufacturing of the color filters.

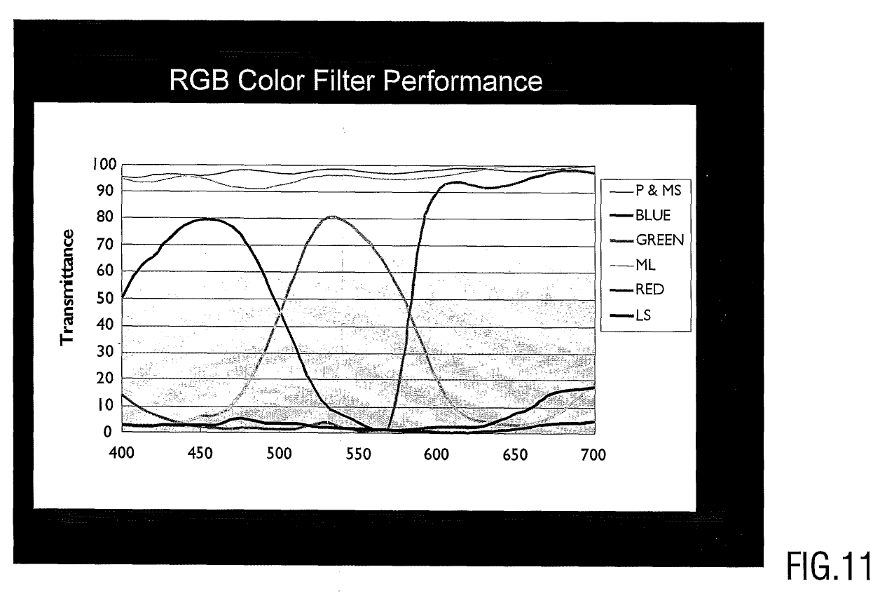

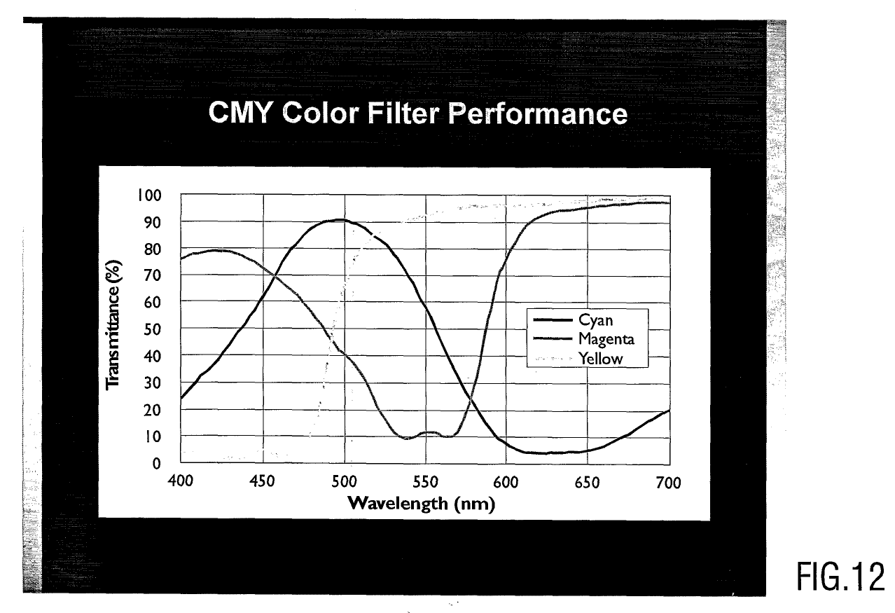

FIGS. 11 and 12 show the transmittance of two different color filters.

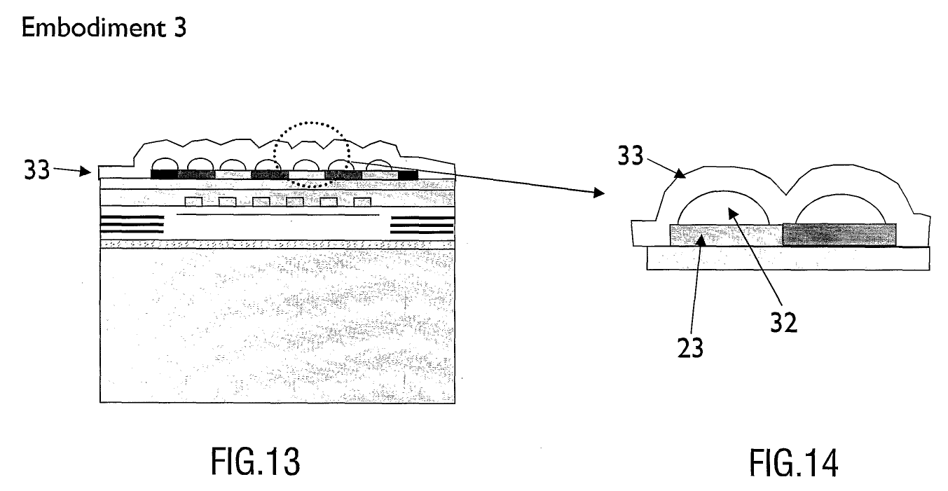

FIGS. 13 to 16 show in a third embodiment the removal of the silicon below the bond pad extensions after manufacturing of the color filters and microlenses.

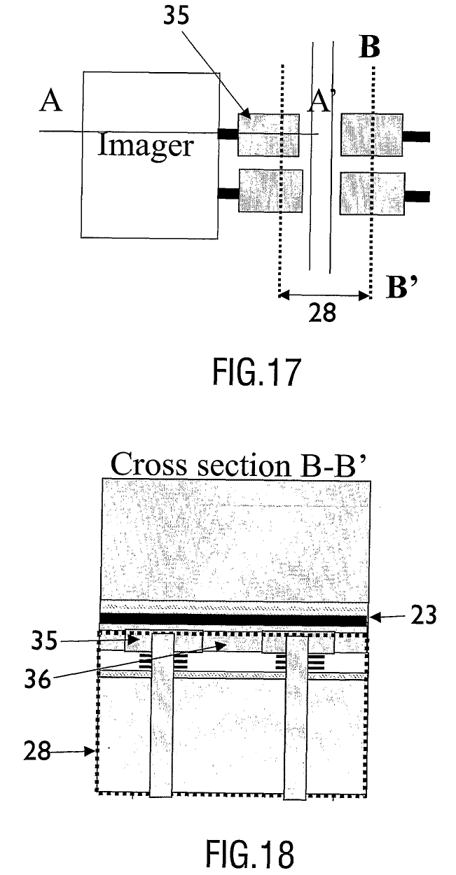

FIGS. 17 to 21 show in a fourth embodiment that the silicon below the bond pad extensions is electrically isolated from the image sensing region by means of an n-type implantation in the semiconductor layer below the leads

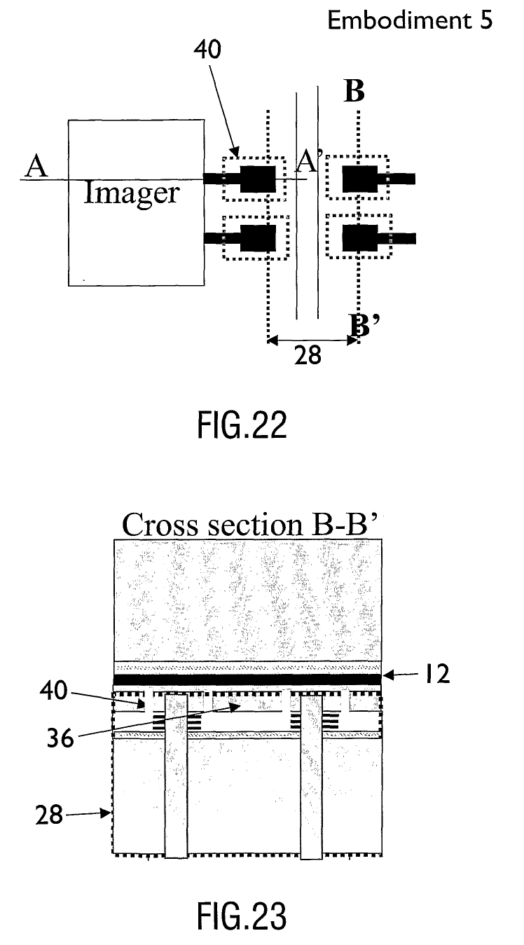

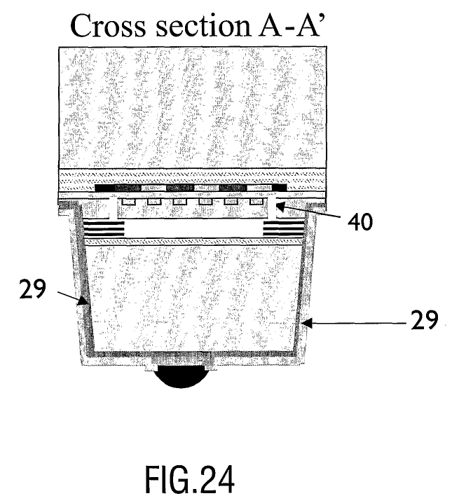

FIGS. 22 to 28 show in a fifth embodiment that the silicon below the bond pad extensions is electrically isolated from the image sensing region by means of deep trenches filled with oxide arranged as a closed loop around the bond pad extensions.

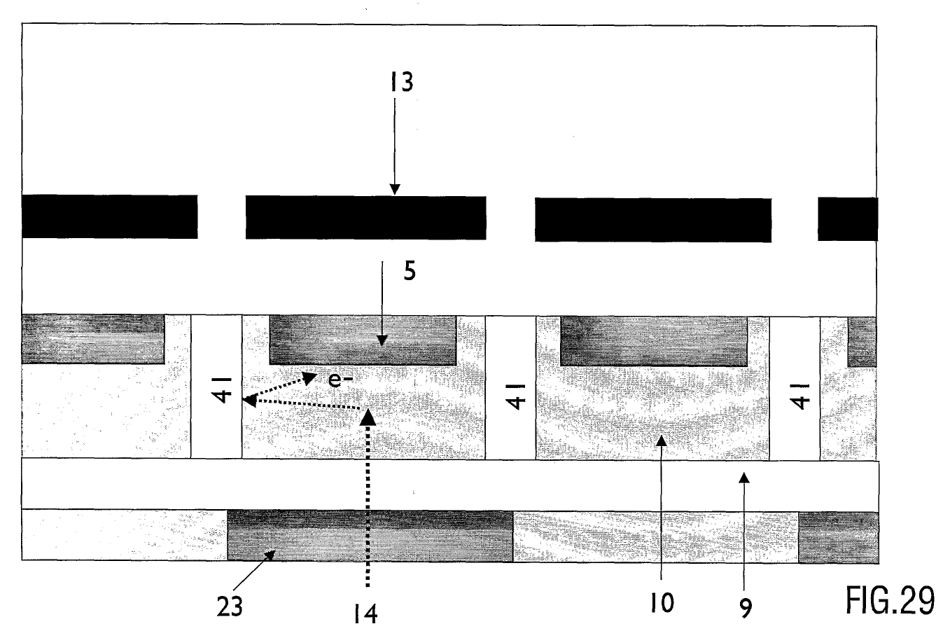

FIG. 29 shows that the pixels are separated by the deep trenches.

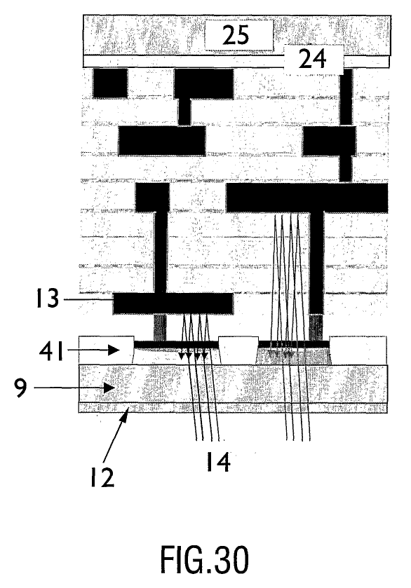

FIG. 30 shows in a sixth embodiment two sensor pixels optimised for two different wavelengths by choosing a different layer of metal. The use of higher level metal layers as reflectors cause different colors to be absorbed at different locations.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes.

The terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

Starting material is a silicon on insulator (SOI) wafer 2 with a silicon substrate 8 and a buried oxide 9 (BOX) thickness of 400 nm.

The epitaxial semiconductor layer 10 is p-type with a typical doping concentration of 10¹⁵ at/cm³ (resistivity of 10 Ohm.cm) and has a thickness of 100 nm.

FIG. 1 schematically shows the manufacture of the image sensor 1 on the SOI wafer 2. In a first step, on top of the epitaxial semiconductor layer 10 of the SOI wafer a silicon layer 11 may be epitaxially grown to a total thickness in the range of 1 to 3 microns. To be used as an image sensor a two-dimensional array of photo-sensitive elements 5 (diodes or transistors) is manufactured in a CMOS process adapted to imaging. In the metallization traject special bond pad extensions 16 are manufactured to make contact between the image sensing region and the external bond pads later in the process. A protective substrate 7 in the form of a glass plate is secured with a layer of glue 24 on the first surface 3 of the wafer.

In FIG. 2 the substrate 8 of the SOI wafer is removed by grinding and a subsequent etch in a solution of KOH. The etch rate of silicon in the KOH solution is much higher (typical 0.75 μm/min) than the etch rate of silicon oxide (typical 1 nm/min). A selectivity of 100 can be easily obtained.

The buried oxide layer 9 functions as an etch stopping layer. The protective substrate 7 facing the CMOS image sensors protects the semiconductor layer from being etched.

The silicon substrate 8 can also be removed by a wet etch in a solution of a mixture of HF/HNO₃ and subsequently in a solution of KOH.

In order to obtain electrical isolation between the semiconductor layer comprising the photosensitive pixel regions (first part 20) and the rest of the semiconductor layer (second part 21), the second part 21 of the semiconductor layer is removed.

To this end, in FIG. 3 the whole structure of FIG. 2 is turned upside down.

A resist mask 22 is provided on top of the image sensing part 20 in FIG. 3A. The resist mask is used to etch the buried oxide 9 (BOX) and the Si epi top layer 10 outside the image sensing part 21, so above the bond pad extensions 16 (FIG. 3B). Although not shown in this Figure, the Si epi layer 10 is also removed above the leads (forming contact from bond pad extension to BGA balls) and above the bond pads. The resist mask 22 is removed afterwards.

Alternatively, the buried oxide 9 can be etched using a resist mask and the silicon epi layer 10 can be etched using an oxide hard mask.

In FIG. 4 the buried oxide 9 (BOX) is provided with color filters 12 and microlenses (not shown in this Figure). The color filters and microlenses are photo sensitive resist layers, which can be provided with photographic techniques. For the alignment of the color fields 23 to the pixel 5 the same alignment marks can be used as in standard CMOS processes. These alignment marks are etched patterns in the silicon epi layer. Because the thickness of the epilayer is in the range of 1-3 μm, the marks are easily detectable by the stepper. In order to expose the wafer from the back-side, special marks are necessary, which are mirrored versions of the standard alignment marks.

In FIG. 5 a second glass plate 25 is secured on the color filter 12 and the microlenses with a second glue layer 26.

In FIG. 6 a compliant layer 27 is provided.

In FIG. 7 the wafer is notched. The notch 28 ends in the upper glue layer 26.

In FIG. 8 metal leads 29 and a solder mask are provided. BGA balls 30 are made.

The process shown in FIGS. 6 to 8 is described in the wafer level package process disclosed in WO95/19645.

In an alternative embodiment shown in FIGS. 7A-B to 8A the bond pad extensions are connected from the back-side.

The second glass plate 25 (having a typical thickness of 400 μm), is sawed forming an opening 50 just above the bond pad extensions 16. The wafer flatness and tolerances in sawing make it very difficult to exactly stop on the metal layers of the bond pad extensions (see FIG. 7A). Therefore, the sawing process may be stopped when there are only a few microns left between the opening 50 and the bond pad extensions 16 (see FIG. 7B).

Subsequently the remaining few microns of glass are removed. Preferably a dry etching technique is used, using e.g. a fluorine containing gas. For wire bonding, preferably the bond pads closest to the semiconductor layer 10 are used. These bond pads closest to the semiconductor layer are formed from a thick metal layer which is suitable for wire bonding 51 (see FIG. 8A).

In the opening 50 a stud (e.g. of Cu) may be placed for stud bumping. Such a stud may be placed on each level of the bond pads, because a stud can be placed on a thin metal layer. Preferably the stud protrudes the surface of the second glass plate 25 for making easily external contact in a stud bumping process such as flip chip.

In this alternative embodiment (FIGS. 7A-B to 8A) an electrical connection is provided from the back-side where the light enters. This is contrary to the FIGS. 7 to 8 where contact is made with solder balls from the other side. In mounting processes for image sensors, it is important that the wire bonding or stud bumping can occur from the side where the active area of the semiconductor is located. For example when die to die bonding occurs with a companion die or when a bonding process like I2MC is used. In several modules a die is mounted to the back-side of a flexible substrate with flip chip techniques. In that case stud bumps have to be provided at the same side where the active area of the semiconductor is located.

Already in the front-end of the CMOS process special measures have to be taken for the separation of the image sensors later in the process.

The image sensors can be separated by first removing the semiconductor layer surrounding the image sensors 21 in a method as described in U.S. Pat. No. 6,177,295.

However this method is not suitable for the manufacture of CMOS image sensors. For a good performance of the image sensor, the thickness of the silicon toplayer 10 is in the range of 1-3 microns (instead of the 100 nm in U.S. Pat. No. 6,177,295). If the semiconductor layer surrounding the image sensing devices is removed, a topography will occur of 1-3 microns.

This topography may cause problems later in the process. It is not possible to manufacture sub-micron devices in an advanced CMOS process on wafers with several microns topography.

In the method according to the invention, the silicon 21 below the bond pad extensions is etched in a later stage of the process. A major advantage of this shift towards later processing, is that the advanced deep sub-micron CMOS process can be done on a planar surface of the wafer.

Alternatively to the method as shown in FIGS. 3A and 3B, in which the silicon below the bond pad extensions is etched before the color filters are manufactured, the removal of the silicon 21 below the bond pad extensions 16 can be done after manufacturing of the color filters. The transparent resist layer 31 is used as a etch mask for etching the oxide layer 9 and subsequently the silicon epi layer 10.

FIGS. 9 and 10 show this second embodiment of the method.

It is very advantageous that the color filter 12 processing now can be done on a planar surface. The color fields 23 are manufactured by spin coating and subsequent development of the color layer. Different color fields 23 are manufactured after each other and are aligned above the pixels 5.

FIGS. 11 and 12 show the color filter performance for visible light.

The transmission for blue, green and red are respectively about 80%, 80% and more than 90%. This RGB filter is applied in mobile phones and webcams.

The transmission for cyan, magenta and yellow are respectively about 80%, 90% and 95%. This CMY filter is applied in video applications.

Because the color filters are made from a photoresist, these layers can also be used as an etch mask for etching the silicon top layer below the bond pad extensions. The first layer of the color process is a transparent layer 31 which is exposed and developed open in an area of the bond pad extensions. The color layers and microlenses are open exposed at the position of the bond pad extensions, so that the BOX oxide 9 and the epi layer 10 can be etched using the color/microlenses sandwich as etch mask.

FIGS. 13 to 16 show an advantageous third embodiment of the method in which the removal of the silicon below the bond pad extensions can be done after manufacturing of the color filters and the microlenses 32.

This embodiment has the advantage of “gapless” microlenses. After depositing the color filters 12 and the microlenses 32, a plasma nitride layer 33 is deposited (see FIG. 13). In this way “gapless microlenses” are formed in FIG. 14. Lenses without this extra layer have a spacing between these lenses, so that the surface of the microlens is smaller than the pixel surface and part of the light can not enter. With this additional layer 33 on top of the micro lenses 32, there is no spacing so that the area of the microlens and the pixel area are the same.

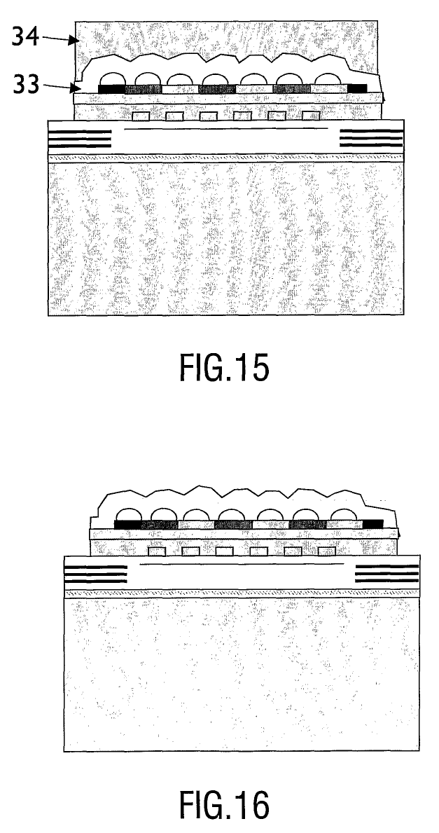

Subsequently a photoresist 34 is provided. The resist above the bond pad extensions 16 is exposed and developed open. The plasma nitride 33, BOX oxide 9 and the silicon epitaxial layer 10 are etched (see FIG. 15). The resist layer 34 on top of the plasma nitride layer may be selectively removed from the plasma nitride by stripping in an oxygen containing plasma (see FIG. 16). Alternatively this transparent resist can remain there.

Compared to the second embodiment the advantages of the third embodiment are:

the color 12 layer and microlens layer 32 are protected against etching steps by means of the plasma nitride layer 33 and the resist layer 34.

gapless microlenses 32 are obtained with a larger microlens area.

Instead of the nitride layer 33, as mentioned above, other materials such as Al can be used. An additional advantage of Al is that it can function as a light shield.

In embodiments 4 and 5, the silicon 21 below the bond pad extensions 16 is not removed, but electrically isolated from the image sensing region.

This may be realised by means of:

an n-type implantation 35 in the semiconductor layer below the leads (embodiment 4) or

trenches 40 filled with oxide arranged as a closed loop around bond pad extensions (embodiment 5).

In embodiment 4, the semiconductor epi layer provided with the light sensitive pixel regions 20 is electrically isolated from the rest of semiconductor layer 21 where the leads 29 will be positioned.

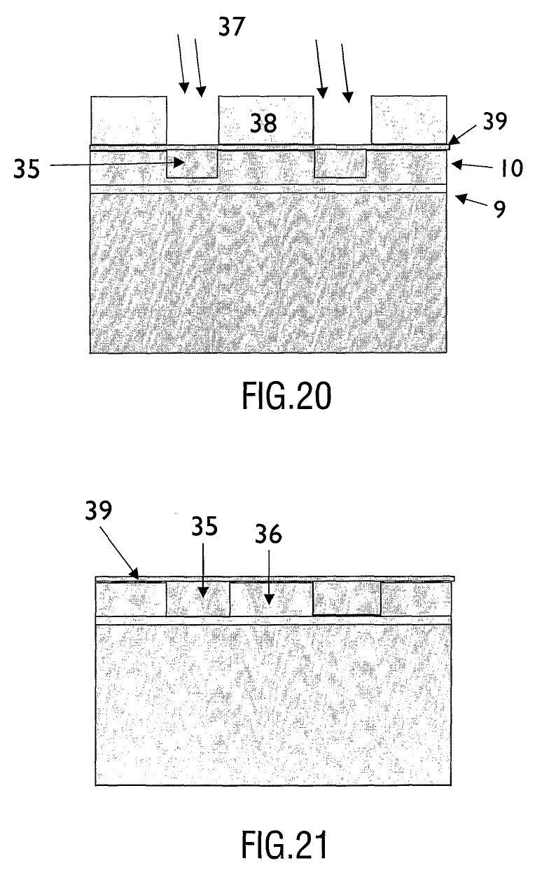

This electrical isolation is obtained by means of an N-type implantation. With the aid of a resist mask, the epi top layer is implanted in an area 35 where later in the process contacts between the leads 29 and the bond pad extensions 16 will be made (See FIG. 17, top view). The N-type (P, As) implantation 37 is done at high energy (in the MeV range) through a resist mask 38. An oxide layer 39 protects the surface (FIG. 20). In order to dope the entire thickness of the epi layer a high temperature anneal is done after removal of the resist layer 38 (see FIG. 21).

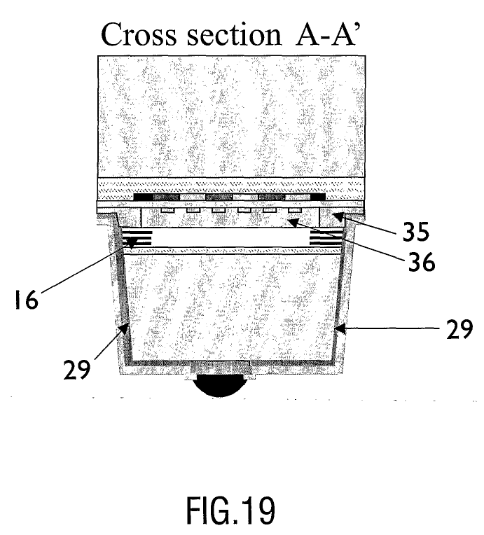

Later on in the process, the metal leads 29 contact the N-type Si 35 and therefore are electrically isolated from the P-type semiconductor layer 36 (see FIG. 18 cross sectional view parallel to notch 28 line B-B′, and FIG. 19 cross sectional view perpendicular to the notch 28, line A-A′)

A big advantage of this method is that no further topography is introduced on the wafer.

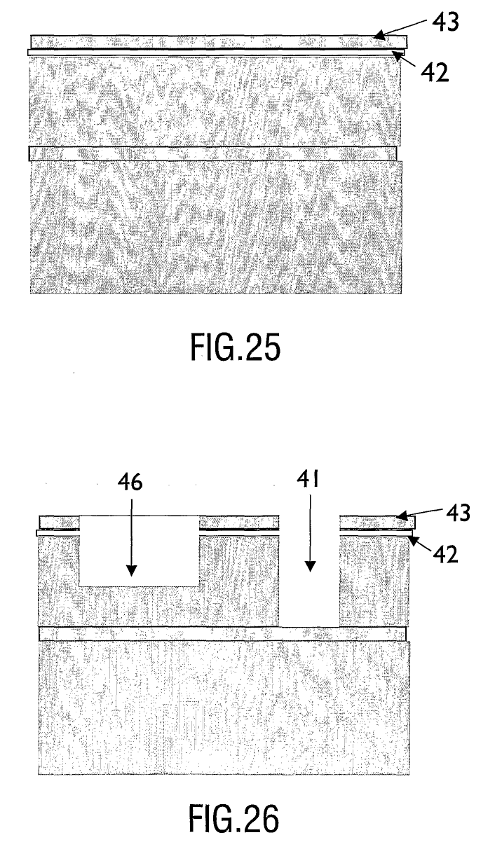

In embodiment 5, the silicon layer where the leads make contact is electrically isolated from the semiconductor layer with the light sensitive pixel regions by means of a loop 40 around the bond pad extensions 16 (See FIGS. 22,23,24). The loop is formed by etched trenches 41 which are filled with electrical isolating material like silicon oxide (See FIGS. 25 to 28). After the trenches are filled with oxide, a planarisation step is performed. Alternatively the trenches may be filled with a thin (thermal) oxide and polysilicon. The polysilicon may be provided in a CVD process.

There are several methods of manufacturing the isolating loop. One of the most elegant solutions is to combine this step with the manufacture of the shallow trench isolation step in conventional CMOS processing.

Just as is the case in STI processing, trenches are etched using an oxide 42 and nitride hard 43 mask, they are filled with oxide 44 and planarised.

However, these STI trenches are not sufficiently deep to be applicable. A subsequent trench etch has to be applied to etch the trench through the entire thickness of the epi layer (3 to 5 microns). The buried oxide layer (BOX) functions as etch stopping layer. FIGS. 25 and 26 show respectively the etching of the shallow trench 46 and the extra deep trench 41. The filling with insulating material and the planarisation step can be combined with the standard STI process.

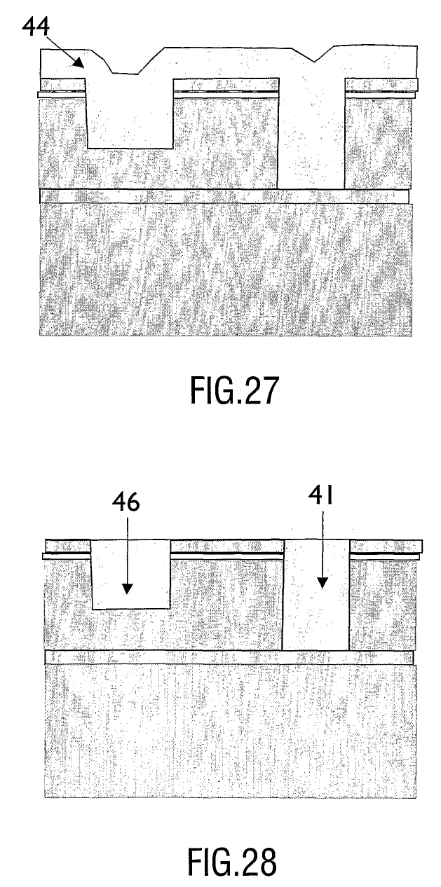

To this end a gapfill material 44 is deposited (FIG. 27). Preferably the width of the deep trench 41 is smaller than two times the thickness of the oxide 44 to be deposited into the trench in order to obtain a good planarisation. Subsequently the wafer is planarised by means of chemical mechanical polishing (CMP) (FIG. 28). Alternatively, the trenches may be filled with a thin (thermal) oxide and polysilicon. The polysilicon may be provided in a CVD process.

This embodiment 5 has the advantage of only one extra mask step and the advantage that there is no further topography introduced in the process.

The pixels of the image sensing part can be separated from each other by means of deep trenches 41. This is schematically shown in FIG. 29. Light enters via a color filter 23 into the light sensitive area of a pixel 5. The filtered light is converted into an electrical current, generated in the depletion layer of the pn junction. The depletion layer of the pn junction may touch the surface of the interface between the BOX and the epi-layer or the sidewall of a deep trench.

It is also possible that the depletion layer is located in the bulk of the epi-layer.

The deep trenches for pixel isolation can be manufactured at the same time as the deep trenches which are used for electrical isolation of the image sensing part 20 from the rest of the epi-layer 21.

In a further advantageous embodiment, the deep trenches are not filled with a dielectric in this stage of the process. The trenches are filled in a next step, in which the planarisation layer (the transparent resist layer of embodiment 2) for the color filter process is provided. The advantage of this method is that the front-end processing is not modified and there are less resist variations in the color filter process.

An additional advantage of these deep trenches is that they can be used as alignment marks. The marks are used to align the color filters and the micro lenses above the light sensitive pixel regions. Because the trenches extend through the entire epi-layer, the stepper may detect these trenches very well in this stage of the process.

In back-side illuminated image sensors the light falls in from the back-side 14 of the semiconductor layer 10. Before entering into the depletion regions of the junctions, which form the light sensitive pixel regions 5, light has to transmit through the semiconductor layer 10.

The absorption of visible light in the semiconductor layer, before entering the depletion region, can be reduced to zero. The depletion region of the junctions touches the transparent optical layer in that particular case.

When the semiconductor layer thickness is much smaller than the total absorption depth of visible light, a certain amount of light will transmit through the semiconductor layer.

This light may be reflected by a metallization pattern 13, which functions as reflector.

To this end a special metallization pattern is designed in the CMOS metallization traject.

The metallization pattern 13 is adapted to function as reflector to re-direct light to the light sensitive pixel regions 5. In order to reduce losses, the metal layer facing the light sensitive regions reflects the light being not absorbed in the semiconductor layer and re-directs the light to the light sensitive pixel regions.

The efficiency of the sensor can be increased by using a multilevel metallization in which the metal layers function as reflectors. FIG. 30 shows two sensor pixels optimised for two different wavelengths by choosing a different layer of metal.

The invention can be applied in CMOS imaging application areas, like webcams and mobile phone cameras, PDAs (personal digital assistants) and DSCs (digital still cameras).

1. Method of manufacturing a back-side (14) illuminated image sensor (1), comprising the steps of:
starting with a wafer (2) having a first (3) and a second (4) surface,
providing light sensitive pixel regions (5) extending into the wafer from the first surface (3),
securing the wafer onto a protective substrate (7) such that the first surface (3) faces the protective substrate (7),
characterized in that the wafer comprises a substrate (8) of a first material with an optical transparent layer (9) and a layer of semiconductor material (10), wherein the substrate (8) is selectively removed from the layer (10) of semiconductor material by using the optical transparent layer (9) as stopping layer.

2. Method as claimed in claim 1, characterized in that the optical transparent layer (9) is a buried oxide layer of an SOI wafer.

3. Method as claimed in claim 2, characterized in that an additional semiconductor layer (11) is epitaxially grown on the layer of semiconductor material, in which the total thickness of the semiconductor layer is less than 5 microns.

4. Method as claimed in claim 1, characterized in that a color filter (12) is provided on the optical transparent layer (9).

5. Method as claimed in claim 1, in which a metallization pattern (13) is provided on the first side (6) of the wafer before securing the wafer onto a protective substrate, characterized in that the metallization pattern is designed such that light entering from the back-side (14) is reflected by the metallization pattern into the light sensitive pixel regions (5).

6. Method as claimed in claim 5, characterized in that the metallization pattern (13) is a multilevel metallization, in which the metal levels (15) function as reflectors such that different colors are absorbed at different light sensitive pixel regions (5).

7. Method as claimed in claim 1, in which a metallization pattern (13) is provided on the first side (6) of the wafer before securing the wafer onto a protective substrate, characterized in that an opening (50) is formed from the back-side to the metallization pattern (13) for making an external electrical connection.

8. Method as claimed in claim 7, characterized in that an electrical conductive stud or a wire bond (51) is formed inside the opening (50).

9. Method as claimed in claim 1, characterized in that the metallization pattern (13) includes bond pad extensions (16) in which, seen in perpendicular projection, a first part (17) of the semiconductor layer having overlap with the bond pad extensions is electrically insulated from a second part (18) of the semiconductor layer having the light sensitive pixel regions.

10. Method as claimed in claim 1, characterized in that isolation between the first part (17) and the second part (18) of the semiconductor layer is formed by trench isolation (19) through the entire semiconductor layer.

11. Method as claimed in claim 1, characterized in that the isolation between the first part and the second part of the semiconductor layer is formed by junction isolation (20).

12. Method as claimed in claims 9, characterized in that the first part of the semiconductor layer is removed after the manufacture of the color filter (12).

13. Method as claimed in claim 9, characterized in that the first part of the semiconductor layer is removed after the manufacture of a microlens.

14. Image sensor, comprising a semiconducting layer (10) having a first (3) and a second (4) surface, the semiconductor layer comprising light sensitive regions (5) extending into the semiconductor layer from the first surface (6), the second surface of the semiconductor layer having an optical transparent layer (9) through which light enters through the semiconductor layer in the light sensitive pixel regions, the first surface of the semiconducting layer facing a protective substrate (7), characterized in that there is a color filter in direct contact with the optical transparent layer.

15. Image sensor as claimed in claim 14, characterized in that
part of the light being not absorbed in the semiconductor layer is re-directed into the light sensitive pixel regions by reflection of a metallization pattern (13).

16. Image sensor as claimed in claim 15, characterized in that the metallization pattern is a multilevel metallization pattern and different colors of light are reflected via different levels of the metal towards different light sensitive pixel regions.

17. Image sensor as claimed in claim 14, characterized in that a metallization pattern (13) provided on the first surface (3) of the semiconductor layer (10) is connected via an opening (50) through the semiconductor layer (10) and the protective layer (7), for making an external electrical connection.

18. Image sensor as claimed in claim 17, characterized in that an electrical conductive stud or a wire bond (51) is formed inside the opening (50).
